(19) United States
(12) Patent Application Publication
(10) Pub. No.: US 2006/0125512 A1
(43) Pub. Date: Jun. 15, 2006

(54) Method and apparatus for inspecting array substrate

(75) Inventors: Nobutaka Itagaki, Tokyo (JP); Hideyuki Norimatsu, Tokyo (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/296,956

(22) Filed: Dec. 8, 2005

(30) Foreign Application Priority Data
Dec. 9, 2004 (JP) 2004-357326

(51) Int. Cl. G01R 31/00

(52) U.S. Cl. 324/770

(57) ABSTRACT

A method for inspecting an active-matrix-display-panel array substrate includes: a first step of applying a voltage V₁ to the data terminal of a transistor while the transistor conducts, bringing the transistor into a non-conductive state, applying a voltage V₁+ΔV to the data terminal, bringing the transistor into a conductive state, and measuring charge ΔQ; a second step of applying a voltage V₀ to the data terminal when the transistor does not conduct and the data terminal voltage is V₃, and measuring a voltage Q₁ flowing through the transistor when the transistor conducts; a third step of applying a voltage V₀′ to the data terminal when the transistor does not conduct and the data terminal voltage is V₄, and measuring charge Q₂ flowing when the transistor conducts; and a fourth step of determining a capacitance of the capacitor based on ΔV, ΔQ, V₀, V₀′, V₃, V₄, Q₁, and Q₂.

### BACKGROUND OF THE INVENTION

1. Field of the Invention

The present invention relates to a method and apparatus for inspecting array substrates in active-matrix display panels. More specifically, the present invention relates to an inspection method and an inspection apparatus which are applicable to the inspection of array substrates used in active-matrix display panels, such as organic electroluminescent (EL) panels and liquid-crystal panels.

2. Description of the Related Art

In recent years, with the advancement of display performance, attention has been focused on flat panel displays, such as liquid crystal panels (hereinafter referred to as “LCDs”) and organic electroluminescent panels or organic light emitting diode (hereinafter referred to as “OLEDs”). In the manufacturing processes of such flat panel display substrates, a test for checking whether the array substrates are formed without any defect is performed (this test will hereinafter be referred to as “array test”). For the array test, it is important to measure the capacitances of pixel-voltage-storing capacitors (hereinafter referred to as “storage capacitors”) for storing data. Specifically, a predetermined voltage is applied to the data terminal of a thin-film transistor (TFT) array to charge the storage capacitor and the amount of charge is read and divided by the voltage value to thereby determine the capacitance of the capacitor.

In the related art, it is often difficult to accurately measure only the capacitance of the storage capacitor. This is because of the parasitic capacitance of the TFT, which serves as a switching device for switching current flowing to the storage capacitor in the array substrate. In the TFT, a layer that provides a source electrode and a layer that provides a data electrode are laminated at two corresponding opposite portions of the top surface of a layer that provides a gate electrode. A space formed between the source electrode and the data electrode generates a parasitic capacitance. During the array test, when a voltage for testing is applied to the TFT data terminal coupled to the data line of the array substrate and charge, or electric charge, flowing into the storage capacitor is measured, there is a problem in that the measurement cannot be accurately performed since the parasitic capacitance in the TFT causes a measurement error.

Examples of the known art for testing arrays include Japanese Unexamined Patent Application Publication No. 2004-93644. Different voltages are applied to each gate electrode in the TFT array in the array substrate twice and the capacitance and the charge stored in a storage capacitor are measured to detect a punch-through voltage abnormality in the array substrate. In the technology described in that document, however, no consideration is given to the influence of the parasitic capacitance generated between the data electrode and the source electrode in the TFT array.

In any array testing, there will be no problem if the parasitic capacitance generated between the data terminal and the source terminal in the TFT, which serves as a switching device, is negligibly small compared to the capacitance of the storage capacitor. Otherwise, there is a problem in that an error occurs in the measurement of the storage capacitance and, consequently, the punch-through voltage cannot be correctly inspected.

### SUMMARY OF THE INVENTION

Accordingly, the present invention has been conceived in view of the foregoing situation, and an object of the present invention is to provide an array-substrate inspection method and an array-substrate inspection apparatus which can perform precise inspection of a storage capacitor by allowing individual measurement of parasitic capacitance generated in a switching device and the capacitance of a storage capacitor.

To achieve the object described above, the present invention provides a method for inspecting an array substrate in an active-matrix display panel. The array substrate has a switching transistor having a data terminal, a source terminal, and a gate terminal, a pixel drive circuit connected to the source terminal of the transistor, and a pixel-voltage storing capacitor connected to the pixel drive circuit and the source terminal. The method includes: a first step of applying a voltage V₁ to the data terminal while the transistor is in a conductive state, bringing the transistor into a non-conductive state, applying a different voltage V₁+ΔV to the data terminal while the transistor is in the non-conductive state, bringing the transistor into the conductive state, and measuring an amount of charge ΔQ flowing through the transistor; and a second step of applying a voltage V₀ to the data terminal when the transistor is in the non-conductive state with the voltage applied to the data terminal being a voltage V₃ different from the voltage V₀, and a potential of the capacitor being V_{C}; and measuring an amount of voltage Q₁ flowing through the transistor when the transistor is brought into the conductive state. The method further includes: a third step of applying a voltage V₀′ to the data terminal when the transistor is in the non-conductive state with the voltage applied to the data terminal being a voltage V₄ different from the voltage V₃, and the potential of the capacitor being the potential V_{C}; and measuring an amount of charge Q2 flowing through the transistor when the transistor is brought into the conductive state; and a fourth step of determining a capacitance C_{S} of the capacitor based on values of ΔV, ΔQ, V₀, V₀′, V₃, V₄, Q₁, and Q2.

In the second step and the third steps, the values of the voltages V₀ and V₀′ may be or may not be equal to each other.

Prior to either or both of the second step and the third step, the voltage applied to the data terminal may be increased, while the gate voltage of the transistor when it is in the conductive state is maintained at a constant value, to thereby bring the transistor into the non-conductive state. This can cause the potential of the transistor to have a value that is obtained by subtracting a threshold voltage Vₜₕ of the transistor from a gate voltage V_{G} of the transistor, that is, to have a value that satisfies V_{C}=V_{G}−Vₜₕ.

According to the present invention, in the fourth step, the capacitance C_{S} of the capacitor can be determined based on equation 1 below:

$${C}_{S} = \frac{Δ V ( {Q}_{1} - {Q}_{2} ) + ( {V}_{4} - {V}_{3} ) Δ Q}{Δ V ( {V}_{4} - {V}_{3} )} \qquad ( 1 )$$

where ΔV′=V₂−V₁.

Further, a parasitic capacitance C_{ds} of the transistor or another transistor can be determined based on equation 2 below:

$${C}_{ds} = \frac{Δ V ( {Q}_{1} - {Q}_{2} )}{( {V}_{4} - {V}_{3} ) Δ Q} \frac{Δ V ( {Q}_{1} - {Q}_{2} ) + ( {V}_{4} - {V}_{3} ) Δ Q}{Δ V ( {V}_{4} - {V}_{3} )} \qquad ( 2 )$$

As another preferred embodiment, instead of satisfying V_{C}=V_{G}−Vₜₕ in the second step or the third step, the method may further include a step of applying, prior to the second step, the voltage V₁ to the data terminal of the transistor when it is in the conductive state; and reducing the gate voltage to bring the transistor into the non-conductive state, while maintaining the voltage V₁ of the data terminal, to thereby set the potential of the capacitor to V₁. The method may also include a step of applying the voltage V₂ to the data terminal of the transistor when it is the conductive state, and reducing the gate voltage to bring the transistor into the non-conductive state, while maintaining the voltage V₂ of the data terminal, to thereby set the potential of the capacitor to V₂.

The present invention further provides an apparatus for inspecting an array substrate in an active-matrix display panel. The array substrate has a switching transistor having a data terminal, a source terminal, and a gate terminal, a pixel drive circuit connected to the source terminal of the transistor, and a pixel-voltage storing capacitor connected to the pixel drive circuit and the source terminal. The apparatus includes a voltage source, a charge measuring circuit, a processing unit, and storing means. The processing unit controls: a first operation of causing the voltage source to apply a voltage V₁ to the data terminal while the transistor is in a conductive state, so as to bring the transistor into a non-conductive state, to apply a different voltage V₁+ΔV to the data terminal while the transistor is in the non-conductive state, and to bring the transistor into the conductive state; causing the charge measuring circuit to measure an amount of charge ΔQ flowing through the transistor; and causing the storing means to store the amount of charge ΔQ; and a second operation of causing the voltage source to apply a voltage V₀ to the data terminal when the transistor is in the non-conductive state, the voltage applied to the data terminal is a voltage V₁ different from the voltage V₀, and a potential of the capacitor is V_{C}; causing the charge measuring circuit to measure an amount of charge Q₁ flowing through the transistor, when the transistor is brought into the conductive state; and causing the storing means to store the amount of charge Q₁. The processing unit further controls a third operation of causing the voltage supply to apply a voltage V₀′ to the data terminal when the transistor is in the non-conductive state with the voltage applied to the data terminal being a voltage V₂ different from the voltage V₁, and the potential of the capacitor being V_{C}; causing the charge measuring circuit to measure an amount of charge Q2 flowing through the transistor, when the transistor is brought into the conductive state; and of causing the storing means to store the amount of charge Q₂. The processing unit performs a fourth operation of determining a capacitance of the capacitor based on values of ΔV, V₀, V₀′, V₃, and V₄ and values of ΔQ, Q₁, and Q₂ stored by the storing means.

Thus, according to the present invention, since the capacitance of the storage capacitor and parasitic capacitance generated in a TFT which serves as a switching device can be measured as individual values, the capacitance of the storage capacitor in the array circuit can be accurately measured. The method and the apparatus of the present invention allow measurement with an accuracy of 1 fF or less.

### BRIEF DESCRIPTION OF THE DRAWINGS

FIGS. 1A to 1C are block diagrams each illustrating a pixel circuit to be tested in the present invention;

FIG. 2 is a circuit diagram schematically showing a pixel circuit to be tested in the present invention;

FIG. 3 is a flow chart showing a measurement procedure according to the present invention;

FIG. 4 is a flow chart of a first step;

FIGS. 5A to 5C are diagrams showing a state transition of the circuit configuration in the first step;

FIG. 6 is a flow chart of a second step;

FIGS. 7A to 7D are diagrams showing a state transition of the circuit configuration in the second step;

FIG. 8 is a flow chart of an alternative example of the second step;

FIG. 9 is a block diagram of a test circuit suitable for carrying out the present invention;

FIG. 10 is a block diagram showing an example of the circuit of a horizontal shift register shown in FIG. 9; and

FIG. 11 is a block diagram showing an example of the circuit of a vertical shift register shown in FIG. 9.

### DESCRIPTION OF THE PREFERRED EMBODIMENTS

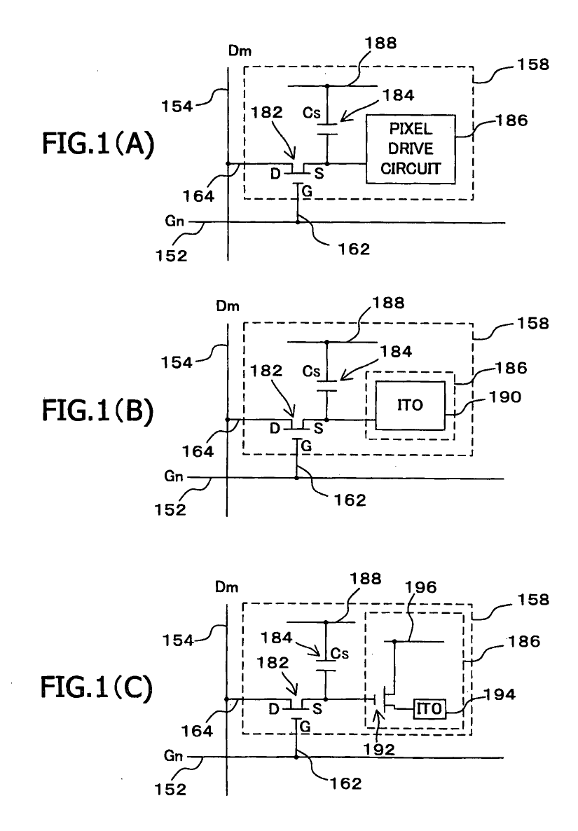

An inspection apparatus and an inspection method for an array circuit according to embodiments of the present invention will be described below with reference to the accompanying drawings. A preferred embodiment for carrying out the present invention will be described with reference to FIGS. 1 to 11.

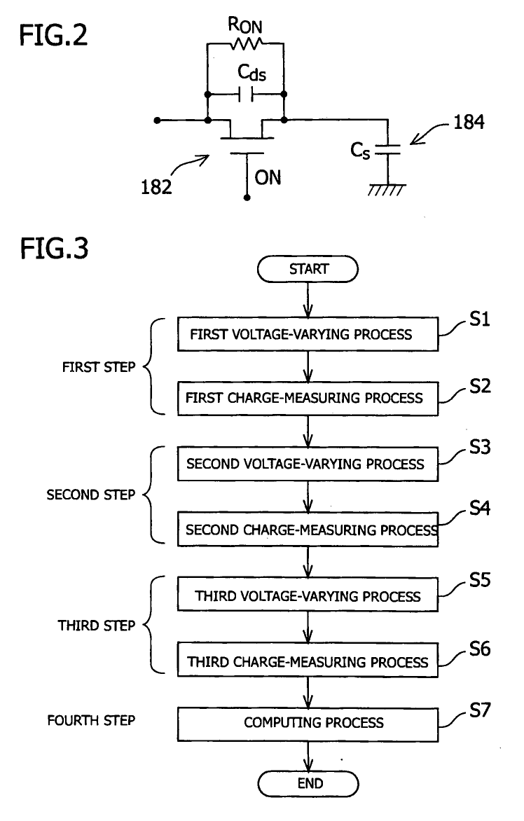

FIGS. 1A to 1C each show one pixel 158, which is an example of the circuit configuration of an LCD or an OLED to be measured in the present invention. FIG. 1A shows a circuit configuration common to an LCD and an OLED. Typically, a pixel drive circuit 186, which includes a transparent electrode made of ITO (indium tin oxide), is connected to a source line coupled to a source terminal (S) of a switching TFT 182 and is switched by the TFT 182. An input is connected to a data terminal (D) of the TFT 182 via a data line Dm (154) and a wiring line 164 (hereinafter referred to as a “data line” for the TFT 182). A capacitor 184 (capacitance C_{S}) for storing a voltage is connected between a ground line 188 and a wiring line that couples the pixel drive circuit 186 and the TFT 182. A gate voltage is supplied to a gate terminal (G) of the TFT 182 and is connected to a gate line Gn (152) via a wiring line 162 (hereinafter referred to as a “gate line” for the TFT 182). Here, m and n are positive integers indicating the column and row numbers in the array. FIG. 1B shows the circuit configuration of an LCD in which the pixel drive circuit 186 includes an ITO electrode 190. FIG. 1C shows the circuit configuration of an OLED in which the pixel drive circuit 186 includes a wiring line 196 for supplying current, a TFT 192, and an ITO electrode 194. As shown in FIG. 2, the TFT 182 has parasitic capacitance C_{ds}. When the TFT 182 is in a conductive state, that is, an ON state, there is resistance R_{ON} between the data terminal and the source terminal.

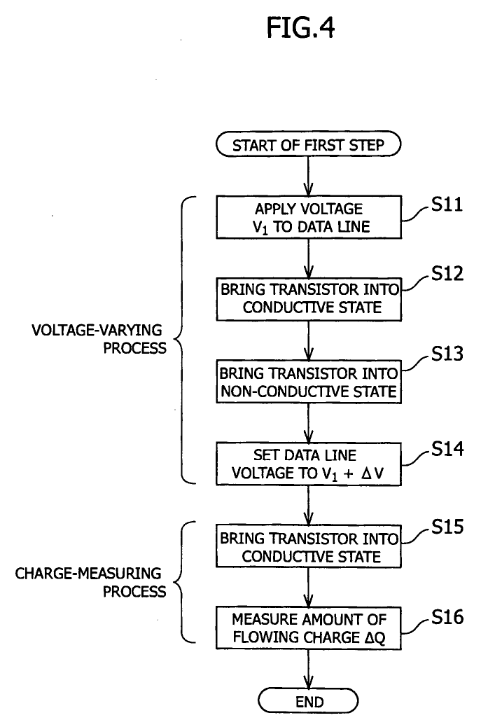

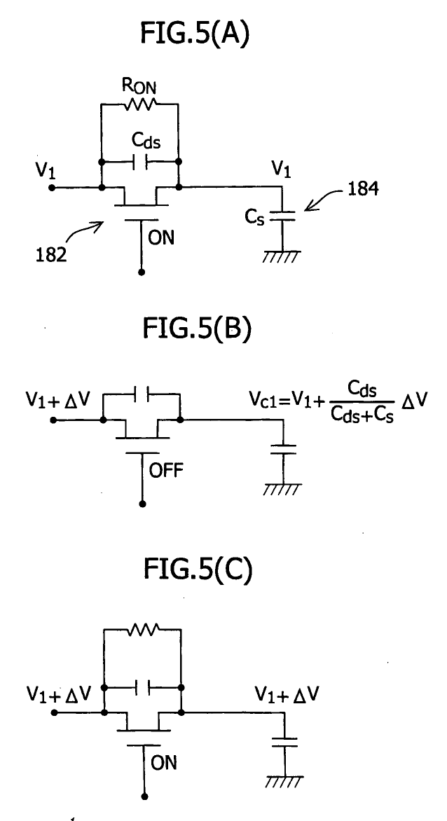

Next, a method for measuring the capacitance of the voltage-storing capacitor 184 in each pixel in the present invention will be described with reference to FIGS. 2 to 7. FIG. 3 is a flow chart showing an embodiment of the entire measuring method of the present invention. First, a first step, including a first voltage-varying process (S1) and a first charge-measuring process (S2), is performed on a pixel array of interest. FIG. 4 is a flow chart showing the first step and FIGS. 5A to 5C are diagrams showing a state transition of the pixel circuit in the first charge-measuring process.

First, a voltage V₁ is applied to the data line 154 for the transistor 182 (S11). V₁ is a voltage that satisfies the expression V₁<V_{Gon}−Vₜₕ, where Vₜₕ indicates a threshold voltage for the transistor 182 and V_{Gon} indicates a gate voltage suitable for bringing the transistor 182 into a conductive state under a data terminal voltage typically applied in the present embodiment. Next, while the data terminal voltage is maintained at V₁, V_{Gon} is applied to a gate voltage V_{G}. As a result, the gate voltage V_{G} becomes greater than V₁+Vₜₕ, so that the transistor 182 in the TFT array is brought into a conductive state (S12). Next, when the transistor 182 in the conductive state, this state is maintained for a predetermined period of time or more. The predetermined period of time refers to the time required until the capacitor 184 is completely charged, i.e., until a voltage across the capacitor 184 can be regarded as being equal to or being sufficiently close to the voltage V₁ at the data terminal, as shown in FIG. 5A. Whether or not the predetermined period of time has passed can be expressed by the time required until an increase in a measurement value of a connected charge meter per unit time is determined to be “0” or sufficiently small. A time constant c in this case is determined by τ=R_{ON}×C_{S}, based on the capacitance C_{S} of the capacitor 184 and the ON resistance R_{ON} of the transistor 182. Whether or not the predetermined period of time has passed can also be determined by connecting an ammeter, instead of the charge meter, and measuring the current value.

Thereafter, a gate voltage V_{Goff} suitable for bringing the transistor 182 into a non-conductive state, that is, an OFF state, under a voltage typically applied to the data terminal is applied to the gate voltage V_{G} to thereby bring the transistor 182 into the non-conductive state (S13). Next, the data terminal voltage is set to V₁+ΔV (S14). The voltage ΔV, however, satisfies V₁+ΔV<V_{Gon}−Vₜₕ. When the transistor 182 is left in the non-conductive state, the voltage across the capacitor 184 becomes V_{C1}, which is different from the data terminal voltage V₁+ΔV, as shown in FIG. 5B, since the capacitor 184 is not connected to the data terminal. In this state, the voltage V_{C1} across the capacitor 184 can be determined by the following equation:

$${V}_{C 1} = {V}_{1} + \frac{{C}_{ds}}{{C}_{ds} + {C}_{S}} Δ V \qquad ( 3 )$$

Next, the first charge-measuring process is performed (S2). Specifically, the voltage V_{Gon} is applied to the gate terminal while the data terminal voltage is maintained at V₁+ΔV, to thereby bring the transistor 182 into the conductive state (S15). When this state is maintained for a certain period of time, as shown in FIG. 5C, the voltage across the capacitor 184 becomes V₁+ΔV, which is equal to the data terminal voltage, thereby reaching a steady state. At this point, the amount of charge ΔQ flowing to the capacitor 184 is expressed by:
ΔQ=C_{S}(V_{C1}−(V₁+ΔV)) (4)
The amount charge ΔQ is measured (S16). Then, the capacitance C_{S} is given by:

$${C}_{S} = \frac{Δ Q + \sqrt{Δ {Q}^{2} + 4 {C}_{ds} Δ Q Δ V}}{2 Δ V} \qquad ( 5 )$$

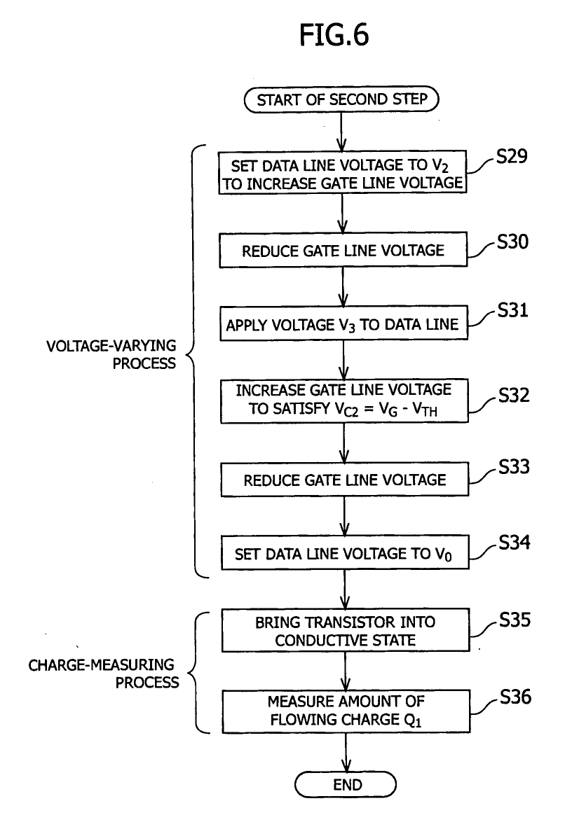

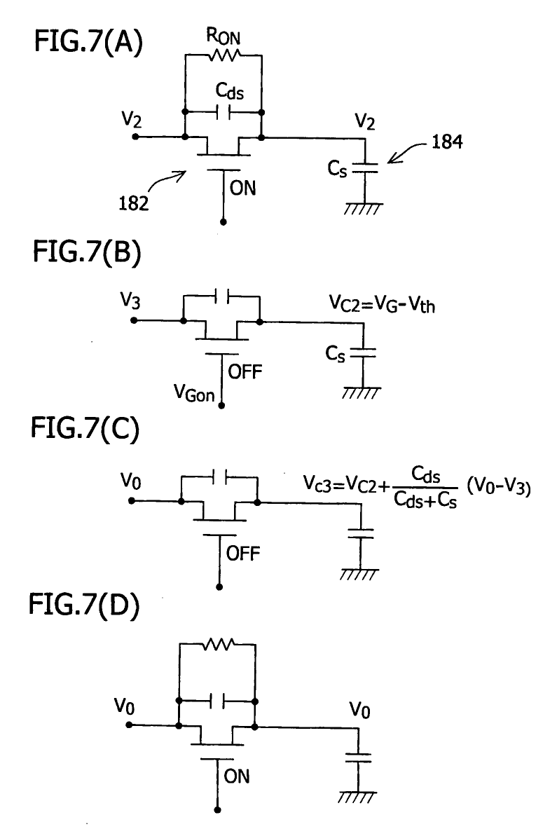

A second step, including a second voltage-varying process (S3) and a second charge-measuring process (S4), is performed. FIG. 6 is a flow chart showing the second step and FIGS. 7A to 7D are diagrams showing a state transition of each pixel in the second voltage-varying process.

First, a voltage V₂ is applied to the data terminal and the voltage V_{Gon} is applied to the gate terminal to bring the transistor 182 into the conductive state, and this state is maintained for a predetermined period of time or more. A voltage V_{C} across the capacitor 184 is initialized to the voltage V₂ (S29). The voltages V₂ and V_{Gon} satisfy V₂<V_{Gon}−Vₜₕ. This voltage V_{Gon} does not necessarily have to be the same as V_{Gon} in the first step. The voltage V₂ and the voltage V₁ may also be equal to each other. In this case, the voltage across the capacitor 184 is V₂, as shown in FIG. 7A. Next, the gate voltage is reduced to V_{Goff} (S30). Subsequently, a voltage V₃ is applied to the data terminal (S31). At this point, the voltage V₃ is higher than the voltage V₂ and satisfies V₃>V_{Gon}−Vₜₕ. Next, the gate voltage V_{G} is increased to V_{Gon} (S32). At this point, although the source terminal voltage increases so as to bring the transistor 182 into the conductive state, the voltage between the gate terminal and the source terminal cannot exceed the threshold voltage Vₜₕ, because of V₃>V_{Gon}−Vₜₕ. Eventually, the transistor 182 does not go into the conductive state and thus remains in the non-conductive state. A voltage V_{C}, or V_{C2}, across the capacitor 184 at this point is given by V_{C2}=V_{G}−Vₜₕ (V_{G}=V_{Gon}) (S32 and FIG. 7B). If the transistor 182 does not operate properly, it should be noted that the voltage V_{C2} at this point does not satisfy V_{C2}=V_{G}−Vₜₕ.

Thereafter, the gate voltage V_{G} is reduced to the voltage V_{Goff} (S33) so that the conductive/non-conductive state of the transistor 182 does not change due to a data-terminal-voltage varying process that is performed next. At this point, since the transistor 182 is in the non-conductive state, the voltage across the capacitor 184 does not become V₃, which is equal to the voltage at the data terminal, but is maintained at V_{C2}=V_{G}−Vₜₕ, expressed by the gate voltage V_{G} and the threshold voltage Vₜₕ of the transistor 182.

Next, while the transistor 182 is in the non-conductive state, the data terminal voltage is set to V₀, which is different from V₃ (S34). The voltage V₀ satisfies V₀<V_{Gon}−Vₜₕ. The voltage V₀ may be the same as either or both of the voltages V₁ and V₂ described above. Thus, the voltage V_{C}, or V_{C3}, across the capacitor 184 at this point becomes as shown in FIG. 7C and as given by the following expression:

$${V}_{C 3} = {V}_{C 2} + \frac{{C}_{ds}}{{C}_{ds} + {C}_{S}} ( {V}_{0} - {V}_{3} ) \qquad ( 6 )$$

Here, the second charge-measuring process (S4) is performed. While the data terminal voltage is maintained at V₀, the gate voltage is increased to the voltage V_{Gon} to thereby turn on the transistor 182 (S35). The amount of charge flowing through the data line is then measured (S36). At this point, when the ON state of the transistor 182 is maintained for a predetermined period of time or more until the steady state is reached after current flows from the data line via the ON resistance R_{ON}, the voltage across the capacitor 184 becomes equal to the data terminal voltage V₀, as shown in FIG. 7D. The amount of charge Q₁ flowing into the capacitor 184 is given by:

$${Q}_{1} = {C}_{S} ( {V}_{C 3} - {V}_{0} ) = {C}_{S} ( {V}_{C 2} - \frac{{C}_{S}}{{C}_{S} + {C}_{ds}} {V}_{0} - \frac{{C}_{ds}}{{C}_{S} + {C}_{ds}} {V}_{3} ) \qquad ( 7 )$$

Additionally, the applied voltage V₃ is replaced with a different voltage V₄ (where V₄>V_{Gon}−Vₜₕ) and the second voltage-varying process and the second charge-measuring process are repeated. The repeated processes correspond to a third step that includes a third voltage-varying process (S5) and a third charge-measuring process (S6). The voltages V₀ in the second voltage-varying process and the third voltage-varying process do not necessarily have to be equal to each other and thus may be different from each other. When the transistor 182 is brought into the non-conductive state (this process corresponds to S33) and the voltage V₀ is applied to the data terminal (this process corresponds to S34). Thereafter, in a fourth step shown in FIG. 3, computation is performed (S7). A voltage V_{C4} across the capacitor 184 is expressed by:

$${V}_{C 4} = {V}_{C 2} + \frac{{C}_{ds}}{{C}_{ds} + {C}_{S}} ( {V}_{0} - {V}_{4} ) \qquad ( 8 )$$

The amount of charge Q₂ flowing from the data line to the capacitor 184 after the transistor 182 is brought into the conductive state is expressed by:

$${Q}_{2} = {C}_{S} ( {V}_{C 4} - {V}_{0} ) = {C}_{3} ( {V}_{C 2} - \frac{{C}_{S}}{{C}_{S} + {C}_{ds}} {V}_{0} - \frac{{C}_{ds}}{{C}_{S} + {C}_{ds}} {V}_{4} ) \qquad ( 9 )$$

Therefore, when ΔV′=V₄−V₃, a difference ΔQ′ between the amount of charge in the second charge-measuring process and the amount of charge in the third charge-measuring process (i.e., ΔQ′=Q₁−Q₂) is given by:

$$Δ {Q}^{′} = {Q}_{1} - {Q}_{2} = \frac{{C}_{ds} {C}_{S}}{{C}_{S} + {C}_{ds}} Δ {V}^{′} \qquad ( 10 )$$

Thus, equation 5 for C_{S} provides the following equations:

$$\begin{matrix}{C}_{S} = \frac{Δ V ( {Q}_{1} - {Q}_{2} ) + Δ {V}^{′} Δ Q}{Δ V Δ {V}^{′}} & ( 11 ) \\ {C}_{ds} = \frac{Δ V ( {Q}_{1} - {Q}_{2} )}{Δ {V}^{′} Δ Q} \frac{Δ V ( {Q}_{1} - {Q}_{2} ) + Δ {V}^{′} Δ Q}{Δ V Δ {V}^{′}} & ( 12 )\end{matrix}$$

Since ΔV and ΔV′ are given, measuring ΔQ, Q₁, and Q₂ (ΔQ′) can determine the capacitance C_{S} of the capacitor 184 and the parasitic capacitance C_{ds} of the transistor 182, respectively, from equations 11 and 12 illustrated above.

As described above, according to a preferred embodiment of the present invention, in addition to the known first step, while a voltage with which the transistor 182 goes into the conductive state, i.e., a voltage that brings the transistor 182 into the conductive state under a data terminal voltage typically used, is applied to the gate in the second and third voltage varying processes (S3 and S5), two selected voltages that cause the voltage between the gate terminal and the source terminal to be less than or equal to the threshold voltage Vₜₕ, thereby bringing the transistor 182 into the non-conductive state, are applied as data terminal voltages, respectively, to cause the voltage across the capacitor 184 to be equal to the voltage V_{G}−Vₜₕ. This scheme is utilized to eliminate the term V_{C2}, thereby making it possible to determine the capacitance C_{S} of the capacitor 184 and the parasitic capacitance C_{ds} of the transistor 182, without actually measuring the voltage V_{C2} of the capacitor.

Although the voltage-varying and charge-measuring processes described above are illustrated with the sequence of the first, second, and the third processes for convenience of description, the sequence for carrying out those processes is arbitrary and thus is not restricted to the embodiment described above. According to another preferred embodiment, the sequence can be such that, after the first step is performed, the second step is performed, the first step is performed again, and the third step and the fourth step are performed. According to still another preferred embodiment, as the result of the first step, either of the results for the first time or the second time the first step is performed can be used. Also, the average of the first-step results for the first time and the second time it is performed can be used. Such an arrangement provides an advantage in that more systematic measurement is possible. Repeating the processes described above while changing data lines to which a voltage is applied allows measurement of the capacitance of the storage capacitor for each pixel.

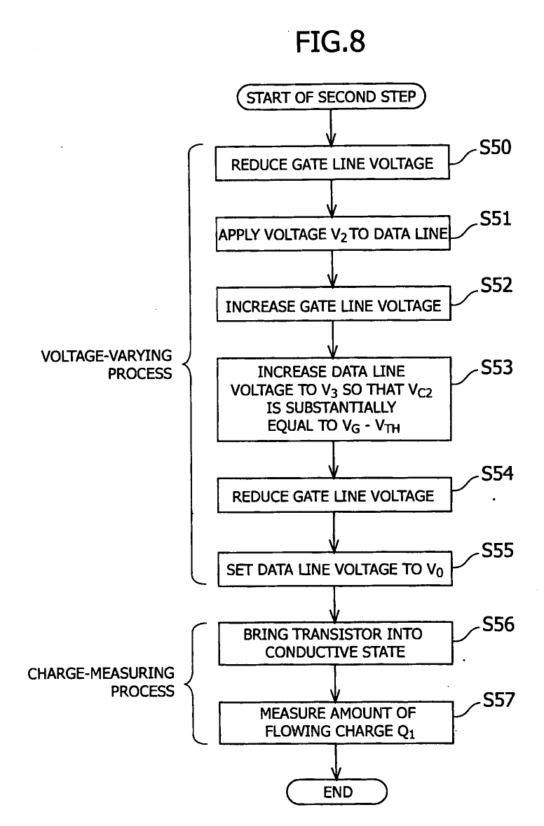

In another embodiment of the present invention, in the second and third voltage-varying processes, a scheme, which is not as accurate as the scheme described above, for causing a voltage across the capacitor 184 to become substantially V_{G}−Vₜₕ can be used instead of processes S29 to S32 shown in FIG. 6. Specifically, referring to FIG. 8, first, the V_{Goff} is applied to the gate terminal to bring the transistor 182 into the non-conductive state (S50). Next, a voltage V₂ that satisfies V₂<V_{G}−Vₜₕ is applied to the data terminal (S51). Subsequently, V_{Gon} is applied to the gate terminal to bring the transistor 182 into the conductive state (S52). Further, the data terminal voltage is increased to a voltage V₃ that satisfies V₃>V_{Gon}−Vₜₕ (S53). As a result, the voltage between the gate terminal and the source terminal becomes less than or equal to the threshold voltage Vₜₕ, so that the transistor 182 goes into the non-conductive state. A voltage V_{C2} across the capacitor 184 becomes substantially V_{G}−Vₜₕ (V_{G}=V_{Gon}). However, since electric charge moves to the capacitor 184 via the parasitic capacitance C_{ds} in the process in which the data terminal voltage is increased to V₃, the accuracy is not so high. Thus, this method is effective for a case in which high accuracy is not required. Since the remaining processes are analogous to process S33 and the subsequent processes shown in FIG. 6, descriptions thereof will not be given hereinafter. In this case, at least two of the voltages V₁, V₂, and V₀ may be equal to each other.

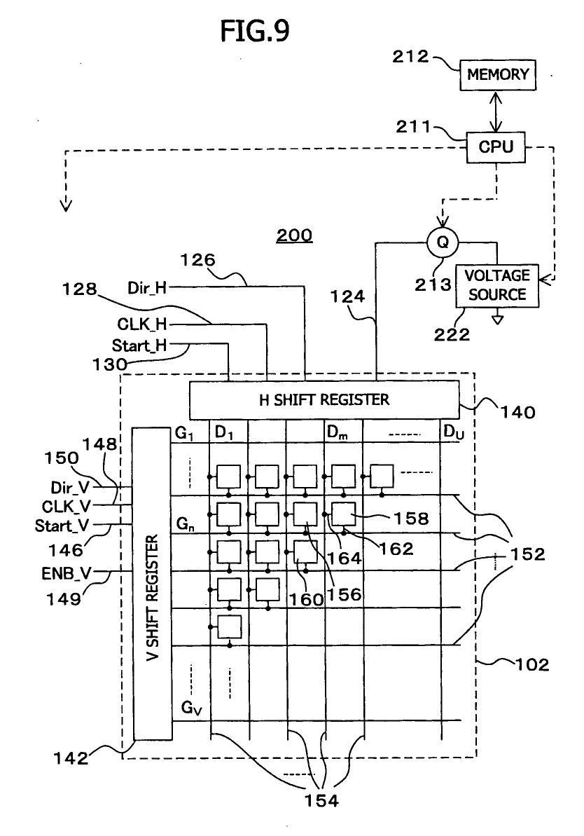

FIG. 9 shows an example of a measuring apparatus 200 that can be used for realizing the method and the apparatus of the present invention. This measuring apparatus 200 includes a variable voltage source 222, a charge meter 213, and a memory 212. The entire operation of the measuring apparatus 200 is controlled by a central processing unit (CPU) 211. The measuring apparatus 200 is connected to a TFT array 102, which includes a plurality of pixels (some of which are denoted with reference numerals 156, 158, and 169). Selection of a gate line 152 by a vertical (V) shift register 142 and selection of a data line 154 by a horizontal (H) shift register 140 can define a data line voltage and a gate line voltage to be applied to a specific pixel. The H shift register 140 is provided with a clock signal terminal CLK_H (128), a pulse input terminal Start_H (130), and a shift direction terminal Dir_H (126). The V shifter register 142 is provided with a clock signal terminal CLK_V (148), a pulse input terminal Start_V (146), a shift direction terminal Dir_V (150), and an enable terminal ENB_V (149). The clock signal terminals 128 and 148, the pulse input terminals 130 and 146, the shift direction terminals 126 and 150, and the enable terminal 149 output timing signals for performing operations described below under the control of the CPU 211.

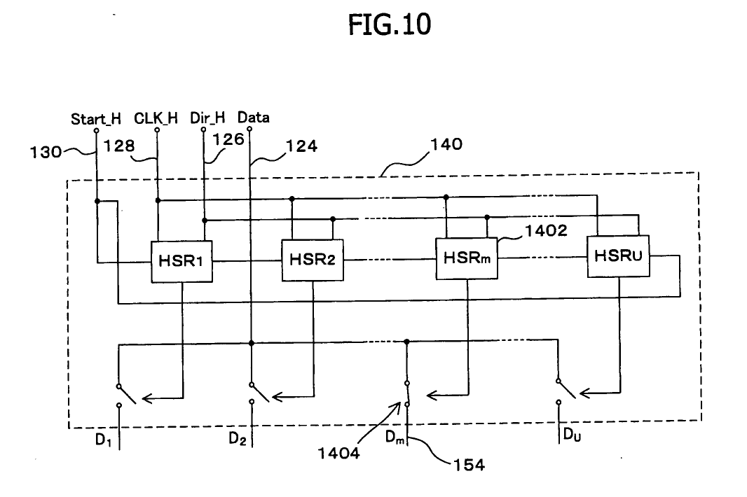

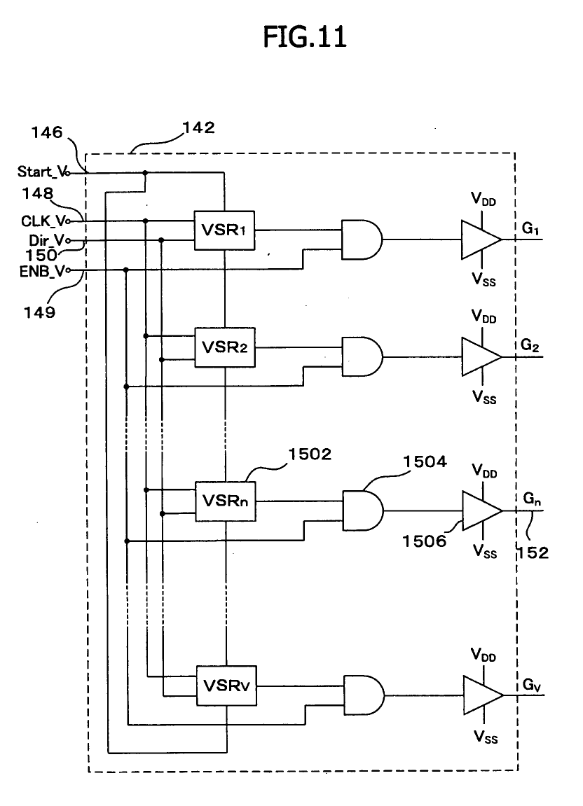

In accordance with a clock signal supplied to the corresponding input terminal, each shift register shifts a signal, supplied to the corresponding pulse input terminal, in a direction defined by a signal supplied to the corresponding shift direction terminal. Examples of the circuits of the H shift register 140 and the V shift register 142 are schematically illustrated in FIGS. 10 and 11, respectively, and the operations thereof will be described below.

Referring to FIG. 10, the H shift register 140 includes U shift registers HSR₁ to HSR_{U}, including HSRm 1402. According to the number of clock signals supplied to the clock terminal CLK_H (128), the H shift register 140 shifts a logic-high signal, supplied to the pulse input terminal Start_H (130), in a direction specified by the shift direction terminal Dir_H (126). Further, the H shift register 140 closes a relay (1404 in this case) coupled to the corresponding shift register (HSRm 1402 in this case) that stores the logic-high signal. As a result, a signal supplied to a data terminal 124 is output to the data line 154 (Dm in the illustrated example). Thus, data lines that have not been selected are released. The H shift register 140 may have an enable terminal. In such a case, the specified relay 1404 is closed, only when the logic of the enable terminal is high. A system for short-circuiting an unselected data line to another signal line may be employed for the H shift register 140.

Referring now to FIG. 11, the V shift register 142 includes V shift registers VSR₁ to VSR_{V}, including VSRn 1502. The V shift register 142 shifts a logic-high signal, supplied to the pulse input terminal Start_V (146), in a direction specified by the shift direction terminal Dir_V (150), according to the number of clock signals supplied to the clock terminal CLK_V (148). In this example, only when a logic-high signal is output from the shift register VSRn 1502 and a logic-high signal is supplied to the enable terminal ENB_V (149), a logic-high signal is output from an AND circuit 1504, which is connected to the output of the shifter register 1502. The output logic-high signal is then buffered and amplified by a buffer 1506 to cause an ON voltage Vₒₙ to be output to the gate line Gn 152. On the other hand, a shift register that has not been selected outputs a logic-low signal, which is buffered and amplified by a corresponding buffer. Consequently, an OFF voltage V_{off} is output to a gate line that has not been selected.

The enable terminal ENV_V (149) may be eliminated from the V shift register 142. In such a case, the AND circuit 1504 is not provided, so that merely selecting a shift register causes the ON voltage Vₒₙ to be output to the gate line.

Referring back to FIG. 9, the variable voltage source 222 for applying a voltage to a selected data line and the charge meter 213 for measuring the amount of charge that moves via the data lines during the application of a voltage from the variable voltage source 222 are connected in series with the power-supply terminal 124 for the H shift register 140. The setting of the variable voltage source 222 and the setting of the charge meter 213 are controlled by the CPU 211 and the measurement value of the charge meter 213 is stored in the memory 212 via the CPU 211.

Each pixel, for example, the pixel 158, in the TFT array 102 is connected to the corresponding gate line (Gn) via the line 162 and is similarly connected to the corresponding data line (Dm) via the line 164.

The measuring apparatus 200 has been illustrated merely as an example, and it is apparent to those skilled in the art that various configurations different from the above-described configuration can be employed to carry out the present invention disclosed in the appended claims. For example, various systems can be employed for the charge meter 213 for measuring the amount of charge movement. In the present invention, systems other than those described above can also be applied to the shift register 140 and/or the V shifter register 142. Furthermore, in the present invention, various systems other than those described above can be applied to the circuits of the LCD and the OLED shown in FIG. 1. In the embodiment described above, although the line 188 has been described as a ground line connected to ground for the sake of simplifying the description, it may be a power-supply line at a different potential. In the description given above, the TFT is an n-type TFT, but the present invention is similarly applicable to a p-type TFT, although the polarity is reversed in such a case.

What is claimed is:

1. A method for inspecting an array substrate in an active-matrix display panel, the array substrate having a switching transistor having a data terminal, a source terminal, and a gate terminal, a pixel drive circuit connected to the source terminal of the transistor, and a pixel-voltage storing capacitor connected to the pixel drive circuit and the source terminal, the method comprising:
a first step of applying a voltage V₁ to the data terminal while the transistor is in a conductive state, bringing the transistor into a non-conductive state, applying a different voltage V₁+ΔV to the data terminal while the transistor is in the non-conductive state, bringing the transistor into the conductive state, and measuring an amount of charge ΔQ flowing through the transistor;
a second step of applying a voltage V₀ to the data terminal when the transistor is in the non-conductive state, the voltage applied to the data terminal is a voltage V₃ different from the voltage V₀, and a potential of the capacitor is V_{C}; and of measuring an amount of voltage Q₁ flowing through the transistor when the transistor is brought into the conductive state;
a third step of applying a voltage V₀′ to the data terminal when the transistor is in the non-conductive state with the voltage applied to the data terminal being a voltage V₄ different from the voltage V₃, and the potential of the capacitor being a potential V_{C}; and then measuring an amount of charge Q₂ flowing through the transistor when the transistor is brought into the conductive state; and
a fourth step of determining a capacitance C_{S} of the capacitor based on values of ΔV, ΔQ, V₀, V₀′, V₃, V₄, Q₁, and Q₂.

2. The method according to claim 1, wherein the voltages V₀ and V₀′ are equal to each other.

3. The method according to claim 1, further comprising, prior to the second step and the third step, a step of applying a voltage V_{Gon} which causes the transistor to go into the conductive state under a data terminal voltage V₂ to the gate terminal; reducing the gate voltage to V_{Goff} to bring the transistor into the non-conductive state; increasing the data terminal voltage V₃ to a voltage which does not cause the transistor to go into the conductive state even when the gate voltage is V_{Gon}; and increasing the gate voltage from V_{Goff} to V_{Gon}, so as to cause the potential of the capacitor to have a value obtained by subtracting a threshold voltage Vₜₕ of the transistor from a gate voltage V_{G} of the transistor.

4. The method according to claim 1, further comprising, prior to the second step and the third step, a step of applying a voltage V_{Gon}, which causes the transistor to go into the conductive state under a data terminal voltage V₂, to the gate terminal; and of increasing the data terminal voltage V₃ to a voltage which does not cause the transistor go into the conductive state even when the gate voltage is V_{Gon}, while the gate voltage is maintained at V_{Gon}, to thereby cause the potential of the capacitor to have a value that is close to a value obtained by subtracting a threshold voltage Vₜₕ of the transistor from a gate voltage V_{G} of the transistor

5. The method according to claim 3, wherein the voltages V₁, V₁+ΔV, and V₂ are smaller than V_{Gon}−Vₜₕ and the voltages V₃ and V₄ are larger than V_{Gon}−Vₜₕ.

6. The method according to claim 3, wherein the voltage V₀ is equal to the voltage V₀′, and at least two of the voltages V₀, V₁, and V₂ are equal to each other.

7. The method according to claim 1, wherein the first step, the second step, and the first step are performed in that order, and then the third step and the fourth step are performed.

8. The method according to claim 2, wherein in the fourth step, the capacitance C_{S} of the capacitor is determined based on equation 1 below:
$${C}_{s} = \frac{Δ V ( {Q}_{1} - {Q}_{2} ) + ( {V}_{4} - {V}_{3} ) Δ Q}{Δ V ( {V}_{4} - {V}_{3} )} . \qquad ( 1 )$$

9. The method according to claim 2, wherein a parasitic capacitance C_{ds} of the transistor or another transistor is determined based on equation 2 below:
$${C}_{ds} = \frac{Δ V ( {Q}_{1} - {Q}_{2} )}{( {V}_{4} - {V}_{3} ) Δ Q} \frac{Δ V ( {Q}_{1} - {Q}_{2} ) + ( {V}_{4} - {V}_{3} ) Δ Q}{Δ V ( {V}_{4} - {V}_{3} )} . \qquad ( 2 )$$

10. An apparatus for inspecting an array substrate in an active-matrix display panel, the array substrate having a switching transistor having a data terminal, a source terminal, and a gate terminal, a pixel drive circuit connected to the source terminal of the transistor, and a pixel-voltage storing capacitor connected to the pixel drive circuit and the source terminal, the apparatus comprising:
a voltage source;
a charge measuring circuit;
a processing unit; and
storing means;
wherein the processing unit controls:
a first operation of causing the voltage source to apply a voltage V₁ to the data terminal while the transistor is in a conductive state, to bring the transistor into a non-conductive state, to apply a different voltage V₁+ΔV to the data terminal while the transistor is in the non-conductive state, and to bring the transistor into the conductive state; causing the charge measuring circuit to measure an amount of charge ΔQ flowing through the transistor; and causing the storing means to store the amount of charge ΔQ;
a second operation of causing the voltage source to apply a voltage V₀ to the data terminal when the transistor is in the non-conductive state with the voltage applied to the data terminal being a voltage V₃ different from the voltage V₀, and a potential of the capacitor being V_{C}; causing the charge measuring circuit to measure an amount of charge Q₁ flowing through the transistor, when the transistor is brought into the conductive state; and causing the storing means to store the amount of charge Q₁; and
a third operation of causing the voltage supply to apply a voltage V₀′ to the data terminal when the transistor is in the non-conductive state with the voltage applied to the data terminal being a voltage V₄ different from the voltage V₃, and the potential of the capacitor being V_{C}; causing the charge measuring circuit to measure an amount of charge Q₂ flowing through the transistor, when the transistor is brought into the conductive state; and causing the storing means to store the amount of charge Q₂; and
the processing unit performs a fourth operation of determining a capacitance of the capacitor based on values of ΔV, V₀, V₀′, V₃, and V₄ and values of ΔQ, Q₁, and Q₂ stored by the storing means.

11. The apparatus according to claim 10, wherein the voltages V₀ and V₀′ are equal to each other.

12. The apparatus according to claim 10, wherein, prior to the second operation and the third operation, the processing unit controls a fifth operation of causing the voltage source to apply a voltage V_{Gon} which causes the transistor to go into the conductive state under a data terminal voltage V₂ to the gate terminal; to reduce the gate voltage to V_{Goff} to bring the transistor into the non-conductive state; to increase the data terminal voltage V₃ to a voltage which does not cause the transistor does to go into the conductive state even when the gate voltage is V_{Gon}; and to increase the gate voltage from V_{Goff} to V_{Gon}, so as to cause the potential of the capacitor to have a value obtained by subtracting a threshold voltage Vₜₕ of the transistor from a gate voltage V_{G} of the transistor.

13. The apparatus according to claim 10, wherein, prior to the second operation and the third operation, the processing unit controls an operation of causing the voltage source to apply a voltage V_{Gon} which causes the transistor to go into the conductive state under a data terminal voltage V₂ to the gate terminal; to increase the data terminal voltage V₃ to a voltage which does not cause the transistor to go into the conductive state even when the gate voltage is V_{Gon}, while the gate voltage is maintained at V_{Gon}, to thereby cause the potential of the capacitor to have a value that is close to a value obtained by subtracting a threshold voltage Vₜₕ of the transistor from a gate voltage V_{G} of the transistor.

14. The apparatus according to claim 12, wherein the voltages V₁, V₁+ΔV, and V₂ are smaller than V_{Gon}−Vₜₕ and the voltages V₃ and V₄ are larger than V_{Gon}−Vₜₕ.

15. The apparatus according to claim 12, wherein the voltage V₀ is equal to the voltage V₀′ and at least two of the voltages V₀, V₁, and V₂ are equal to each other.
